(19) United States
(12) Patent Application Publication
(10) Pub. No.: US 2026/0344021 A1
(43) Pub. Date: Oct. 29, 2026

(54) PLANAR MOSFET INTEGRATED WITH SCHOTTKY BARRIER DIODE WITH MESA STRUCTURE

(71) Applicant: Microchip Technology Incorporated, Chandler, AZ (US)

(72) Inventor: Shesh Pandey, Gilbert, AZ (US)

(73) Assignee: Microchip Technology Incorporated, Chandler, AZ (US)

(21) Appl. No.: 19/265,848

(22) Filed: Jul. 10, 2025

Related U.S. Application Data
(60) Provisional application No. 63/796,940, filed on Apr. 29, 2025.

(51) Int. Cl. H10D 84/80; H10D 8/01; H10D 8/60; H10D 30/01; H10D 30/66; H10D 62/83; H10D 62/832; H10D 64/64

(52) U.S. Cl. CPC H10D 84/811; H10D 8/60; H10D 30/66; H10D 62/83; H10D 62/8325; H10D 64/64; H10D 8/051; H10D 30/0291

(57) ABSTRACT

An apparatus comprising a substrate; a Schottky barrier diode comprising a metal layer and a mesa structure, the mesa structure comprising a first portion of the substrate, wherein the first portion of the substrate extends vertically from a second portion of the substrate; and a planar metal-oxide-semiconductor field-effect transistor (MOSFET) comprising at least a portion of the second portion of the substrate, wherein the planar MOSFET is coupled in parallel with the Schottky barrier diode.

### CROSS-REFERENCE TO RELATED APPLICATION

This application claims the benefit of U.S. Provisional Patent Application No. 63/796,940, filed Apr. 29, 2025.

### TECHNICAL FIELD

The present disclosure relates generally to power semiconductor devices, and more specifically to a planar metal-oxide-semiconductor field-effect transistor (MOSFET) integrated with a Schottky barrier diode having a mesa structure.

### BACKGROUND

A power semiconductor device is an electronic component to efficiently and reliably control and convert electrical power at relatively high voltages and currents. Unlike regular signal-level semiconductors used in low-power applications, in some instances power semiconductor devices may be optimized for switching and amplifying large amounts of energy. Power semiconductor devices may be used in a variety of applications, such as motor drives, power supplies, renewable energy systems, electric vehicles, and the like.

### SUMMARY OF THE INVENTION

Aspects provide a planar MOSFET integrated with a Schottky barrier diode having a mesa structure.

In one aspect, an apparatus comprises a substrate; a Schottky barrier diode comprising a metal layer and a mesa structure, the mesa structure comprising a first portion of the substrate, wherein the first portion of the substrate extends vertically from a second portion of the substrate; and a planar metal-oxide-semiconductor field-effect transistor (MOSFET) comprising at least a portion of the second portion of the substrate, wherein the planar MOSFET is coupled in parallel with the Schottky barrier diode.

In another aspect, a system comprises a package comprising a substrate; a Schottky barrier diode comprising a metal layer and a mesa structure, the mesa structure comprising a first portion of the substrate, wherein the first portion of the substrate extends vertically from a second portion of the substrate; and a planar metal-oxide-semiconductor field-effect transistor (MOSFET) comprising at least a portion of the second portion of the substrate, wherein the planar MOSFET is coupled in parallel with the Schottky barrier diode.

In yet another aspect, a method comprises forming a Schottky barrier diode comprising a metal layer and a mesa structure, the mesa structure comprising a first portion of a substrate, wherein the first portion of the substrate extends vertically from a second portion of the substrate; and forming a planar metal-oxide-semiconductor field-effect transistor (MOSFET) comprising at least a portion of the second portion of the substrate, wherein the planar MOSFET is coupled in parallel with the Schottky barrier diode.

### BRIEF DESCRIPTION OF THE DRAWINGS

FIG. 1 illustrates a planar metal-oxide-semiconductor field-effect transistor (MOSFET) integrated with a Schottky barrier diode with a mesa structure, in accordance with any of the examples disclosed herein.

FIG. 2 illustrates a planar MOSFET integrated with a Schottky barrier diode with a mesa structure and an additional metal layer, in accordance with any of the examples disclosed herein.

FIG. 3 illustrates a schematic representation of a planar MOSFET integrated with a Schottky barrier diode with a mesa structure, in accordance with any of the examples disclosed herein.

FIGS. 4A-4C illustrate a flow for manufacturing a planar MOSFET integrated with a Schottky barrier diode with a mesa structure, in accordance with any of the examples disclosed herein.

FIG. 5 illustrates a P-type planar MOSFET integrated with a Schottky barrier diode with a mesa structure, in accordance with any of the examples disclosed herein.

FIG. 6 illustrates a system comprising a semiconductor device package comprising a planar MOSFET integrated with a Schottky barrier diode with a mesa structure, in accordance with any of the examples disclosed herein.

### DETAILED DESCRIPTION

A Schottky barrier diode (SBD) connected in parallel with a metal-oxide-semiconductor field-effect transistor (MOSFET) is a common circuit in electronics applications. The addition of the SBD to the MOSFET may allow the resulting circuity to handle reverse current more efficiently (particularly during a switching event). The structure of a MOSFET may inherently include a parasitic diode commonly referred to as a body diode, that is relatively slow. Conversely an SBD is typically very fast and may have a lower forward voltage. Accordingly, during reverse conduction, the SBD may conduct first because of its lower forward voltage, preventing the slower body diode of the MOSFET from turning on. This may provide various benefits, such as reduced switching losses, avoidance of undesired charge storage, and reduced negative stressful effects on the MOSFET (e.g., bipolar degradation).

Various examples of the present disclosure provide novel architectures for integrating a MOSFET and an SBD on the same substrate. In some examples, the SBD may include at least one metal layer formed on a mesa structure with planar MOSFET gates proximate opposite sides of the mesa structure. Integrating a MOSFET with an SBD onto the same substrate in accordance with various examples described herein may provide various technical advantages (e.g., relative to coupling a MOSFET on a first substrate to an SBD on a second substrate via a plurality of wires), such as reduced area consumed by the devices, reduced wiring, lower switching losses, reduced gate to drain capacitance, or reduced parasitic capacitances or inductances.

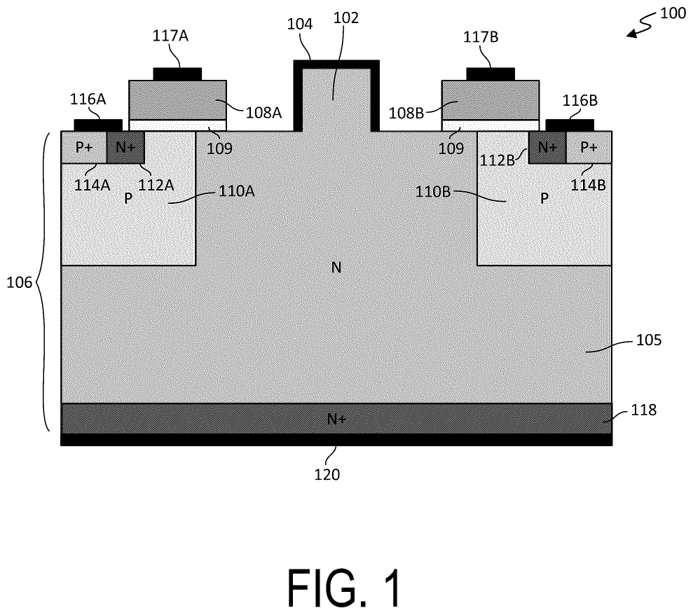

FIG. 1 illustrates a portion of a die 100 comprising a planar MOSFET integrated with an SBD with a mesa structure 102, in accordance with any of the examples disclosed herein. In this example, the die 100 comprises an N-type substrate 106, such as a substrate comprising doped silicon or silicon carbide.

The SBD comprises the mesa structure 102 and a metal layer 104 in contact with at least a portion of the mesa structure 102. The mesa structure 102 may be a portion of the substrate 106 and may protrude vertically from another portion of the substrate 106 (e.g., from top of the drift region 105). In this example, the mesa structure 102 comprise the same N-type semiconductor as the portion of the substrate from which the mesa structure 102 protrudes.

The mesa structure 102 may include a protruding region of semiconductor material of a substrate elevated above the surrounding area of the substrate. In some examples, the mesa structure 102 may have a substantially planar (e.g., flat) top surface (or at least a portion of the top surface may be substantially planar). The side surfaces (e.g., sidewalls) of the mesa structure 102 may be substantially vertical or tapered or sloped at any suitable angle. In some examples, the portion of the substrate around the side surfaces of the mesa structure 102 may be substantially planar.

Metal layer 104 may be formed over or around the mesa structure 102. In some examples, the metal layer 104 may comprise one or more conductive materials, such as aluminum, copper, other metal, or other suitable material.

In some examples, at least portions of the surfaces of the mesa structure (e.g., the top surface or the side surfaces) are in contact with the metal layer 104. In some instances, the metal layer 104 contacts the entire surface area of the mesa structure that protrudes from the substrate. Thus, all surfaces of the mesa structure 102 may be entirely in contact with the metal layer 104.

The interface between the metal layer 104 and the mesa structure 102 forms the SBD, with the metal layer 104 functioning as the anode and the mesa structure 102 functioning as the cathode of the SBD.

The increased surface area of the metal layer 104 around the surfaces of the mesa structure 102 may result in an SBD with an increased capacity for current (e.g., relative to an SBD with a metal layer that is deposited on top of a substrate in a planar fashion). This architecture including a metal layer on a mesa structure provides increased flexibility for meeting design objectives, as an increase in the height of the mesa structure 102 may result in an increase in the current carrying capacity of the SBD due to the increase in the surface area of the metal layer 104 that is in contact with the semiconductor material of the mesa structure.

The MOSFET comprises a pair of gates 108A and 108B adjacent to opposing side surfaces of the mesa structure 102. Thus, at least a portion of the mesa structure 102 may be between the gates 108A and 108B. In some examples, the gates 108A and 108B may be planar gates (e.g., the gates may have a larger dimension in the lateral direction than the vertical direction). The gates 108A and 108B may comprise a conductive material, such as (e.g., heavily doped) polycrystalline silicon or a metal. Gate contacts 117A and 117B may be on top of the respective gates and may comprise one or more conductive materials, such as aluminum, copper, other metal, or other suitable material.

A gate oxide 109 may be formed between the gates and the substrate 106. For example, a gate oxide 109 may be formed between a gate 108A and the drift region 105, P-well 110A, and N+ doped region 112A. As another example, another gate oxide 109 may be formed between a gate 108B and the drift region 105, P-well 110B, and N+ doped region 112B. In various examples, the gate oxide 109 may comprise any suitable oxide, such as silicon dioxide or hafnium oxide (e.g., with a high k value), or other suitable insulating material.

The MOSFET also comprises a pair of source regions, including P-wells 110A and 110B formed within the substrate 106. N+ doped regions 112A and 112B and P+ doped regions 114A and 114B are formed within the P-wells 110A and 110B. The respective N+ doped regions 112 are formed adjacent to the respective P+ doped regions 114. Metal layer 116A (e.g., a first source contact) is formed on P+ doped region 114A and N+ doped region 112A and metal layer 116B (e.g., a second source contact) is formed on P+ doped region 114B and N+ doped region 112B. In some examples, the metal layers 116A and 116B may comprise one or more conductive materials, such as aluminum, copper, other metal, or other suitable material.

The substrate also includes an N+ doped region 118 which may be in contact with a drain contact 120. In various examples, one or more of the drain contact 120, the source contacts 116, the gate contacts 117, or the metal layer 104 may comprise the same conductive material(s).

In various examples, the MOSFET and the SBD are power semiconductor devices. A power semiconductor device may include any suitable semiconductor device that can accommodate high voltage (e.g., between 10V-8000V, but not limited thereto) applied to one or more terminals or high current (e.g., between 5 A-1000 A, but not limited thereto) flowing through one or more terminals. In some examples, the MOSFET and the SBD are the only two semiconductor devices formed on the substrate of a die.

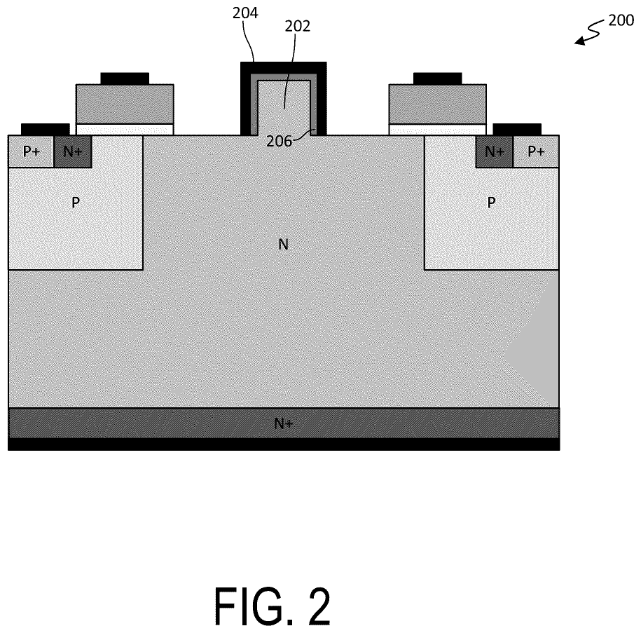

FIG. 2 illustrates a portion of a die 200 comprising a planar MOSFET integrated with an SBD with a mesa structure 202 and a second metal layer 206, in accordance with any of the embodiments disclosed herein. In this example, the architecture is similar to the example of FIG. 1, but includes the second metal layer 206 in between (e.g., and in contact with) the metal layer 204 and the mesa structure 202 (where the metal layer 204 and the mesa structure 202 may have any suitable features of metal layer 104 and mesa structure 102).

In some examples, the second metal layer 206 may improve the performance of the SBD by reducing the forward voltage of the SBD even further (e.g., through a low on-state resistance (Rₒₙ) such that conductance through the SBD occurs quickly when the appropriate electric field is applied). In various examples, the difference between the bandgap of the second metal layer 206 and the bandgap of the material of the substrate (that includes the mesa structure 202) is smaller than the difference between the bandgap of the metal layer 204 and the bandgap of the material of the substrate. In various examples, the bandgap of the second metal layer 206 is lower than the bandgap of the metal layer 204. In some examples, the second metal layer 206 includes titanium, nickel, or other metal.

In some examples, at least portions of the surfaces of the mesa structure 202 (e.g., the top surface or the side surfaces) are in contact with the second metal layer 206. In some instances, the metal layer 206 contacts the entire surface area of the mesa structure that protrudes from the substrate. Thus, all surfaces of the mesa structure 202 may be entirely in contact with the second metal layer 206.

Similarly, at least portions of the outer surfaces of the second metal layer 206 (e.g., the top surface or the side surfaces) are in contact with the metal layer 204. In some instances, the second metal layer 206 is completely surrounded on the sides and top by the metal layer 204.

In various examples, the second metal layer 206 may have a thickness that is greater than, less than, or substantially equal to the thickness of the metal layer 204. Although the metal layers have any suitable thicknesses, in some examples, the metal layer 204 has a thickness between 1 micrometer and 10 micrometers, while the second metal layer 206 has a thickness between 10 and 500 nanometers.

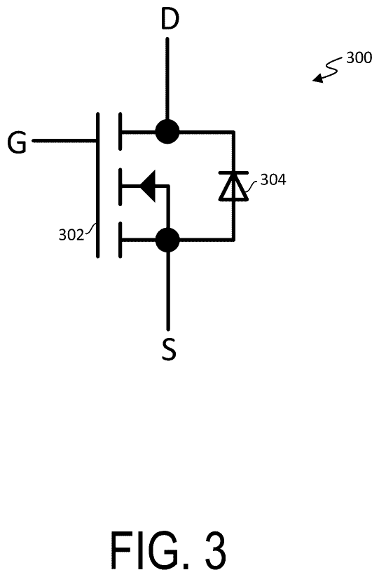

FIG. 3 illustrates a schematic representation of a circuit 300 comprising a planar MOSFET integrated with an SBD with a mesa structure on the same substrate, in accordance with any of the examples disclosed herein. Thus, the schematic may represent the devices on the dies of FIG. 1 or FIG. 2 (or a variation thereof).

In this example, the circuit includes an N-type MOSFET 302 in parallel with an SBD 304. The anode of the SBD 304 is coupled to the source of the N-type MOSFET 302, while the cathode of the SBD 304 is coupled to the drain of the N-type MOSFET 302. In various examples, such coupling may be accomplished in part through forming wires or other traces electrically conductively coupling the outer metal layer of the SBD (e.g., metal layer 104 or metal layer 204) to the source contacts (e.g., 116A or 116B) of the MOSFET. The cathode of the SBD is coupled to the drain through the substrate (e.g., 106). The body/bulk terminal of the N-type MOSFET 302 is also connected to the source in this example.

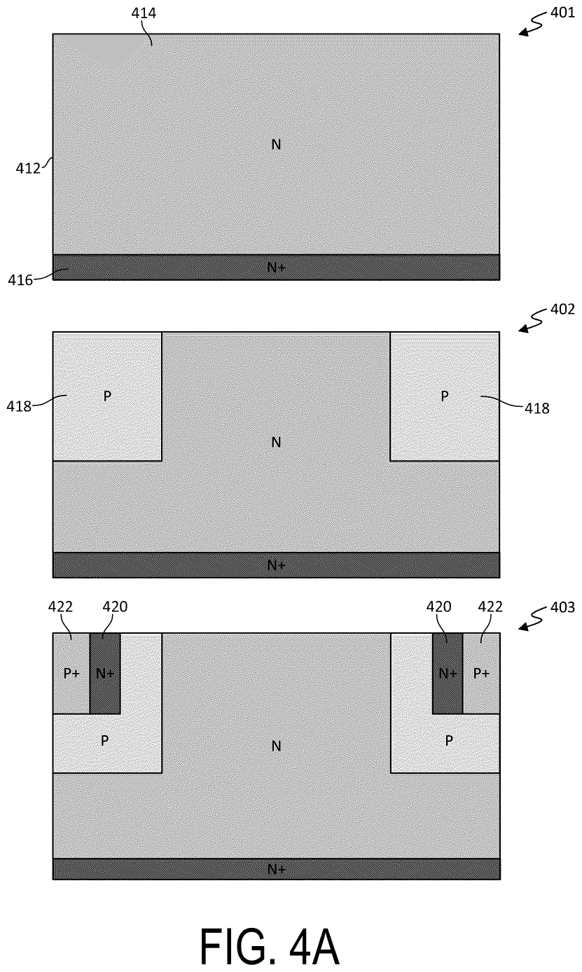

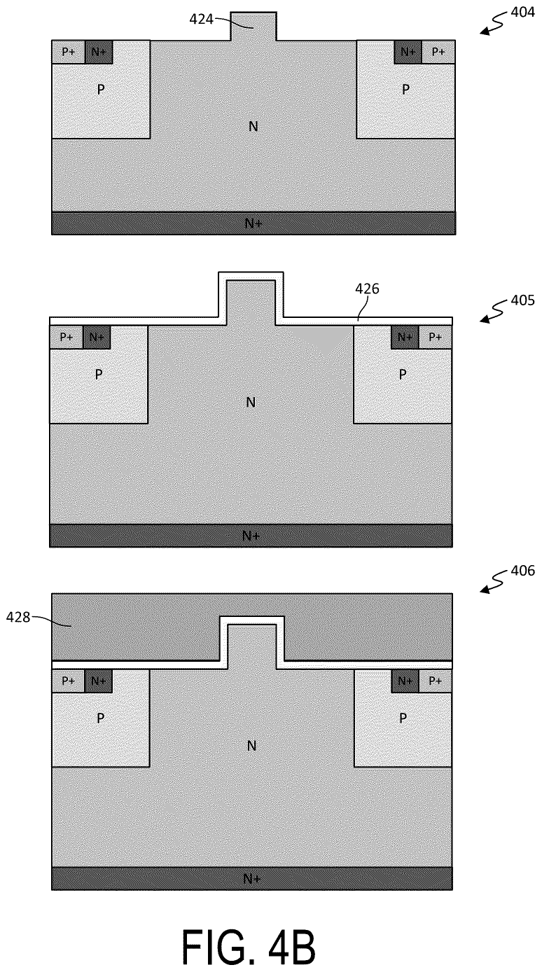

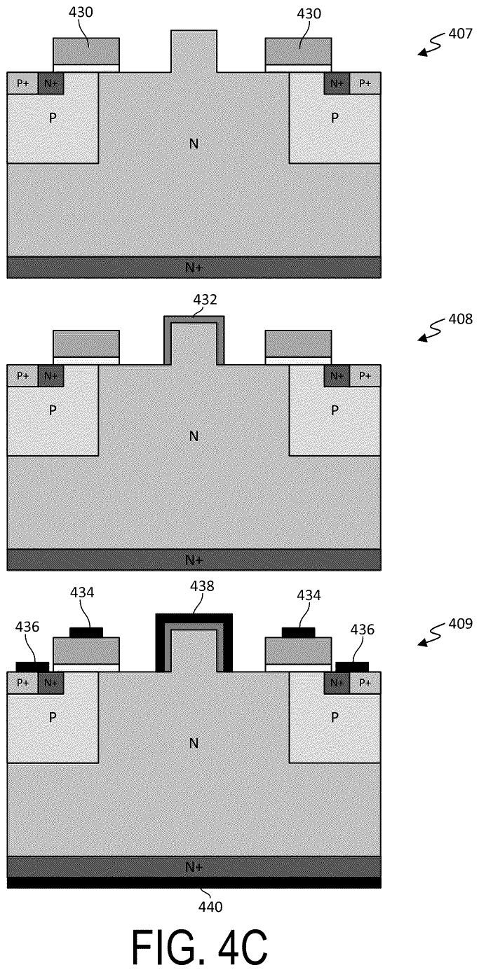

FIGS. 4A-4C illustrate a flow for manufacturing a planar MOSFET integrated with an SBD with a mesa structure, in accordance with any of the embodiments disclosed herein.

In phase 401, a substrate 412 is provided. The substrate 412 may include an N− doped region 414 and an N+ doped region 416 that is more heavily doped than the N− doped region 414. In some instances, the substrate 412 may be included on a wafer comprising silicon or silicon carbide (or other suitable semiconducting material). In various examples, the regions 414 or 416 of the original wafer may initially have a greater thickness and may be reduced to the desired size via any suitable method (e.g., etching, grinding, or other method). The thickness or doping concentration of the substrate 412 may be based on the voltage rating specified for the resulting MOSFET.

In phase 402, P-wells 418 are formed within the substrate 412. For example, a mask may be applied to the top of the substrate 412 and then a P-type dopant (e.g., aluminum or boron) may be implanted or diffused into the substrate 412 to form the P-wells 418.

In phase 403, another mask is applied and an N-type dopant (e.g., phosphorous, arsenic, antimony) is implanted or diffused to form N+ doped regions 420 within the P-wells 418. In some examples, the N+ doped regions 420 have substantially the same concentration of dopants as the N+ doped region 416, though in other examples, the concentration of these respective regions may vary. The N+ doped region 416 and the N+ doped regions 420 may have higher dopant concentrations than the N− doped region 414 (e.g., such that their resistivity is very low), as these regions will interface with the drain and source contacts respectively.

Another mask is applied and a P-type dopant is implanted or diffused to form P+ doped regions 422 within the P-wells 418. The P+ doped regions 422 have a higher concentration of dopants than the P-wells 418. The doping concentration may be very high as this region is to contact the source contact and thus an ohmic contact is desired.

At phase 404, a mask is applied and portions of the N− doped region 414 of the substrate 412, P-wells 418, N+ doped regions 420, and P+ doped regions 422 are etched away, resulting in the formation of a mesa structure 424 that protrudes vertically from the remainder of the substrate 412.

At phase 405, an oxide layer 426 is formed (e.g., grown through thermal oxidation, deposition, or other method) over the top surfaces of the N− doped region 414, P-wells 418, N+ doped regions 420, P+ doped regions 422, and mesa structure 424. The oxide material may include, e.g., silicon oxide, hafnium oxide, or other insulating material.

At phase 406, a gate material 428 is formed on the oxide layer 426 (e.g., through deposition). The gate material may comprise, e.g., polycrystalline silicon or other suitable material.

At phase 407, portions of the gate material 428 and the oxide layer 426 are removed (e.g., etched away) to form gates 430 with underlying oxide layer material between the gates and the substrate.

At phase 408, metal layer 432 is formed around the mesa structure 424 (e.g., through masking and deposition). In some examples, this phase may be omitted (e.g., if a single metal layer is to be formed around the mesa structure).

At phase 409, a mask is applied and a conductive material (e.g., contact metal) is deposited to form gate contacts 434, source contacts 436, and a metal layer 438 around the mesa structure. In some examples, prior to formation of the contacts 434, 436, and metal layer 438, one or more dielectric layers may be applied over the structure shown. A mask may then be applied and the dielectric layer(s) may be etched in the areas where the contacts 434, 436 and metal layer 438 are to be formed and then a conductive material (e.g., aluminum, copper, or other metal or alloy) may be formed (e.g., through deposition) in these areas to form the contacts 434, 436 and metal layer 438. Drain contact 440 is also formed at phase 409.

Although not shown, after the contacts 434, 436 and metal layer 438 are formed, a plurality of wires may be formed to connect the source contacts 436 to the metal layer 438 and to connect respective pins of a package to the source contacts 436, gate contacts 434, and drain contact 440.

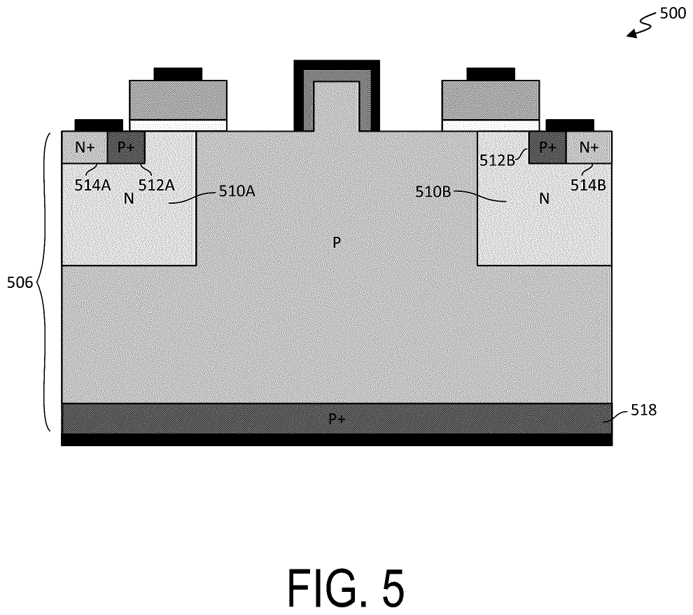

FIG. 5 illustrates a die 500 comprising a P-type planar MOSFET integrated with a Schottky barrier diode with a mesa structure, in accordance with any of the examples disclosed herein. The various regions of the die 500 may have any suitable characteristics of corresponding regions of die 100 or 200. However, the doping of the semiconductor material of the substrate of die 500 is adapted for a P-type MOSFET.

For example, N-wells 510A and 510B are formed in a P-type substrate 506. N+ doped regions 514A and 514B are formed in the N-wells. P+ doped regions 512A and 512B are formed in the N-wells adjacent to the N+ doped regions 514A and 514B.

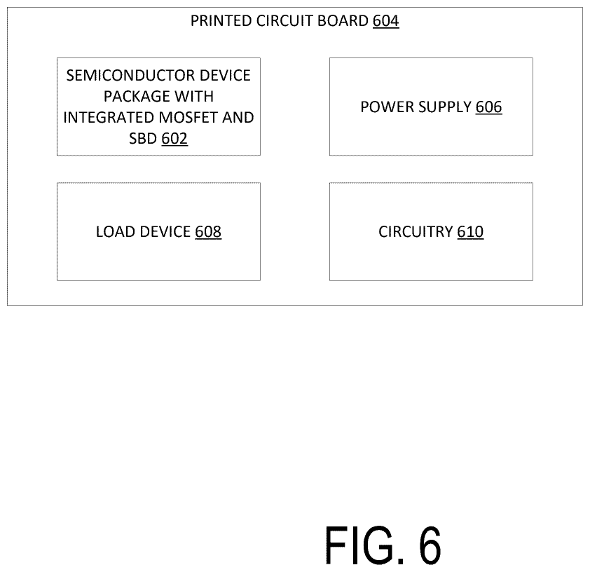

FIG. 6 illustrates a system 600 comprising a semiconductor device package 602 comprising a planar MOSFET integrated with an SBD with a mesa structure, in accordance with any of the examples disclosed herein. The system 600 includes a printed circuit board 604 and various components connected to the printed circuit board. In the example depicted, these components include semiconductor device package 602, power supply 606, load device 608, and circuitry 610. The components may be coupled together in any suitable manner, such as through conductive traces on the semiconductor device package 602.

The semiconductor device package 602 may include any suitable semiconductor device package with a planar MOSFET integrated with an SBD with a mesa structure, such as those described herein or variations thereof.

One or more power supplies 606 may provide electrical power to the components attached to the printed circuit board 604. A power supply 606 may include any suitable source of electrical power, such as, for example, a direct current power supply, an alternating current power supply, or a battery.

Load device 608 may comprise any suitable device connected to, powered by, or controlled by the semiconductor device package 602. For example, the load device 608 may include an electrical or mechanical device, such as a motor, solenoid, actuator, lighting device, battery pack, capacitor bank, power supply, inverter, heater, amplifier, or other suitable device.

Circuitry 610 may include any other suitable circuitry of the system 600, such as one or more integrated circuits, microcontrollers, processors, resistors, capacitors, diodes, transistors, inductors, transformers, switches, or other suitable circuitry.

In various examples, one or more of the illustrated components (or additional components) may be located off of the printed circuit board 604 and coupled to the printed circuit board 604 via any suitable connectors.

As used herein, the term “or” is intended to be inclusive rather than exclusive. That is, unless otherwise indicated or as would be apparent to one of skill in the art, the use of “or” is to be interpreted to mean “and/or.” For example, the phrase “A or B” is to be understood to mean “A, B, or both A and B.” The singular terms “a,” “an,” and “the” are intended to encompass their plural counterparts as well, unless it is clear from the context that a different interpretation is intended. Herein, when a list of items is preceded by phrases such as “at least one of” or “one or more of,” it is intended to allow for any combination of the listed elements.

The terms “above”, “over,” “under,” “between,” and “on,” as used herein, describe the relative positioning of components or materials. For instance, one layer being over or under another layer may encompass direct contact of the layers or the presence of one or more intermediate layers. Similarly, a layer described as being between two others may be in contact with both other layers or separated by one or more additional layers. Conversely, when a layer is “on” another layer, at least a portion of the layer is in direct physical contact with the underlying layer.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

Example 1 includes an apparatus comprising a substrate; a Schottky barrier diode comprising a metal layer and a mesa structure, the mesa structure comprising a first portion of the substrate, wherein the first portion of the substrate extends vertically from a second portion of the substrate; and a planar metal-oxide-semiconductor field-effect transistor (MOSFET) comprising at least a portion of the second portion of the substrate, wherein the planar MOSFET is coupled in parallel with the Schottky barrier diode.

Example 2 includes the subject matter of Example 1, and wherein the planar MOSFET comprises a first gate and a second gate, wherein at least a portion of the mesa structure is between the first gate and the second gate.

Example 3 includes the subject matter of any of Examples 1 and 2, and wherein the metal layer contacts at least a portion of the mesa structure.

Example 4 includes the subject matter of any of Examples 1-3, and wherein the metal layer contacts a top surface of the mesa structure.

Example 5 includes the subject matter of any of Examples 1-4, and wherein the metal layer contacts at least one side surface of the mesa structure.

Example 6 includes the subject matter of any of Examples 1-5, and further including a second metal layer on the metal layer.

Example 7 includes the subject matter of any of Examples 1-6, and wherein the metal layer comprises titanium or nickel, and wherein the second metal layer comprises aluminum or copper.

Example 8 includes the subject matter of any of Examples 1-7, and further including at least one conductive wire that contacts the second metal layer and a source contact of the planar MOSFET.

Example 9 includes the subject matter of any of Examples 1-8, and further including at least one conductive wire that contacts the metal layer and a source contact of the planar MOSFET.

Example 10 includes the subject matter of any of Examples 1-9, and wherein the substrate comprises silicon.

Example 11 includes the subject matter of any of Examples 1-10, and wherein the substrate comprises silicon carbide.

Example 12 includes a system comprising a package comprising a substrate; a Schottky barrier diode comprising a metal layer and a mesa structure, the mesa structure comprising a first portion of the substrate, wherein the first portion of the substrate extends vertically from a second portion of the substrate; and a planar metal-oxide-semiconductor field-effect transistor (MOSFET) comprising at least a portion of the second portion of the substrate, wherein the planar MOSFET is coupled in parallel with the Schottky barrier diode.

Example 13 includes the subject matter of Example 12, and wherein the planar MOSFET comprises a first gate and a second gate, wherein at least a portion of the mesa structure is between the first gate and the second gate

Example 14 includes the subject matter of any of Examples 12 and 13, and wherein the package comprises a plurality of pins, wherein the plurality of pins are connected to a drain contact, a source contact, and a gate contact of the planar MOSFET.

Example 15 includes the subject matter of any of Examples 12-14, and further including a printed circuit board, wherein the package is connected to the printed circuit board.

Example 16 includes the subject matter of any of Examples 12-15, and further including an electrical or mechanical device coupled to the package through the printed circuit board.

Example 17 includes a method comprising forming a Schottky barrier diode comprising a metal layer and a mesa structure, the mesa structure comprising a first portion of a substrate, wherein the first portion of the substrate extends vertically from a second portion of the substrate; and forming a planar metal-oxide-semiconductor field-effect transistor (MOSFET) comprising at least a portion of the second portion of the substrate, wherein the planar MOSFET is coupled in parallel with the Schottky barrier diode.

Example 18 includes the subject matter of Example 17, and wherein the planar MOSFET comprises a first gate and a second gate, wherein at least a portion of the mesa structure is between the first gate and the second gate.

Example 19 includes the subject matter of any of Examples 17 and 18, and further including a second metal layer on the metal layer of the Schottky barrier diode.

Example 20 includes the subject matter of any of Examples 17-19, and wherein the metal layer contacts a plurality of side surfaces and a top surface of the mesa structure.

While the concepts of the present disclosure are susceptible to various modifications and alternative forms, specific examples thereof have been shown in the drawings and described herein in detail. However, the concepts of the present disclosure are not limited to the particular forms disclosed, but on the contrary, all modifications, equivalents, and alternatives consistent with the present disclosure and the appended claims are also covered. Moreover, all examples described herein may be combined in any manner.

1. An apparatus comprising:
a substrate;
a Schottky barrier diode comprising a metal layer and a mesa structure, the mesa structure comprising a first portion of the substrate, wherein the first portion of the substrate extends vertically from a second portion of the substrate; and
a planar metal-oxide-semiconductor field-effect transistor (MOSFET) comprising at least a portion of the second portion of the substrate, wherein the planar MOSFET is coupled in parallel with the Schottky barrier diode.

2. The apparatus of claim 1, wherein the planar MOSFET comprises a first gate and a second gate, wherein at least a portion of the mesa structure is between the first gate and the second gate.

3. The apparatus of claim 1, wherein the metal layer contacts at least a portion of the mesa structure.

4. The apparatus of claim 3, wherein the metal layer contacts a top surface of the mesa structure.

5. The apparatus of claim 3, wherein the metal layer contacts at least one side surface of the mesa structure.

6. The apparatus of claim 1, further comprising a second metal layer on the metal layer.

7. The apparatus of claim 6, wherein the metal layer comprises titanium or nickel, and wherein the second metal layer comprises aluminum or copper.

8. The apparatus of claim 6, further comprising at least one conductive wire that contacts the second metal layer and a source contact of the planar MOSFET.

9. The apparatus of claim 1, further comprising at least one conductive wire that contacts the metal layer and a source contact of the planar MOSFET.

10. The apparatus of claim 1, wherein the substrate comprises silicon.

11. The apparatus of claim 1, wherein the substrate comprises silicon carbide.

12. A system comprising:
a package comprising:
a substrate;
a Schottky barrier diode comprising a metal layer and a mesa structure, the mesa structure comprising a first portion of the substrate, wherein the first portion of the substrate extends vertically from a second portion of the substrate; and
a planar metal-oxide-semiconductor field-effect transistor (MOSFET) comprising at least a portion of the second portion of the substrate, wherein the planar MOSFET is coupled in parallel with the Schottky barrier diode.

13. The system of claim 12, wherein the planar MOSFET comprises a first gate and a second gate, wherein at least a portion of the mesa structure is between the first gate and the second gate.

14. The system of claim 12, wherein the package comprises a plurality of pins, wherein the plurality of pins are connected to a drain contact, a source contact, and a gate contact of the planar MOSFET.

15. The system of claim 12, further comprising a printed circuit board, wherein the package is connected to the printed circuit board.

16. The system of claim 15, further comprising an electrical or mechanical device coupled to the package through the printed circuit board.

17. A method comprising:
forming a Schottky barrier diode comprising a metal layer and a mesa structure, the mesa structure comprising a first portion of a substrate, wherein the first portion of the substrate extends vertically from a second portion of the substrate; and
forming a planar metal-oxide-semiconductor field-effect transistor (MOSFET) comprising at least a portion of the second portion of the substrate, wherein the planar MOSFET is coupled in parallel with the Schottky barrier diode.

18. The method of claim 17, wherein the planar MOSFET comprises a first gate and a second gate, wherein at least a portion of the mesa structure is between the first gate and the second gate.

19. The method of claim 17, further comprising a second metal layer on the metal layer of the Schottky barrier diode.

20. The method of claim 17, wherein the metal layer contacts a plurality of side surfaces and a top surface of the mesa structure.
